(19) United States
(12) Patent Application Publication
(10) Pub. No.: US 2017/0141265 A1
(43) Pub. Date: May 18, 2017

(54) Semiconductor Chip and Method for Producing a Semiconductor Chip

(71) Applicant: OSRAM Opto Semiconductors GmbH, Regensburg (DE)

(72) Inventor: Juergen Off, Regensburg (DE)

(21) Appl. No.: 15/317,957

(22) PCT Filed: Jun. 3, 2015
(86) PCT No.: PCT/EP2015/062446

§ 371 Date: Dec. 11, 2016

(30) Foreign Application Priority Data
Jun. 12, 2014 (DE) 10 2014 108 301.6

(51) Int. Cl. H01L 33/22; H01L 33/32; H01L 33/00

(52) U.S. Cl. CPC H01L 33/22; H01L 33/007; H01L 33/32

(57) ABSTRACT

A semiconductor chip and a method for producing a semiconductor chip are disclosed. In an embodiment, the semiconductor chip includes a semiconductor layer sequence and a structured substrate including a surface, wherein the surface is in contact with the semiconductor layer sequence, wherein the surface has a structure of depressions, each depression is delimited at an underside by a smooth end region, or wherein the surface has a structure of elevations, each elevation is delimited at a top side by a smooth end region, and wherein the end regions are laterally spaced apart with respect to one another.

This patent application is a national phase filing under section 371 of PCT/EP2015/062446, filed Jun. 3, 2015, which claims the priority of German patent application 10 2014 108 301.6, filed Jun. 12, 2014, each of which is incorporated herein by reference in its entirety.

### TECHNICAL FIELD

A semiconductor chip is provided, preferably an optoelectronic, particularly preferably a radiation-emitting semiconductor chip. Furthermore, a method for producing a semiconductor chip of this type is provided.

### BACKGROUND

Radiant power is an important parameter in a radiation-emitting semiconductor chip. Said power is influenced by the internal quantum efficiency which is determined, inter alia, by the crystal quality of the semiconductor chip on the one hand and by the radiation efficiency on the other hand. For example, in a radiation-emitting semiconductor chip formed of an even sapphire substrate and a nitride semiconductor layer sequence arranged thereon, radiation losses occur at the interface between the nitride semiconductor layer sequence and the sapphire substrate due to total reflection, leading to reduced radiation efficiency. The sapphire substrate may be structured in order to reduce such radiation losses. However, compared to a smooth semiconductor substrate, this may affect internal quantum efficiency since dislocation density may be increased and crystal quality may deteriorate due to the limited choice of growth parameters for optimum deposition in a growth process on a structured semiconductor substrate, for example.

### SUMMARY OF THE INVENTION

Embodiments of the invention provide a semiconductor chip with an improved crystal quality and radiant power, respectively. Further embodiments provide a method for producing a semiconductor chip with an improved crystal quality and radiant power, respectively.

According to at least one embodiment, the semiconductor chip comprises a semiconductor layer sequence and a structured substrate. The substrate preferably comprises or consists of a semiconductor material. Furthermore, the semiconductor chip is preferably an optoelectronic, particularly preferably a radiation-emitting semiconductor chip. In particular, the structured substrate is at a surface in contact with the semiconductor layer sequence, the surface having a structure of depressions each delimited at the underside by a smooth end region, or having a structure of elevations each delimited at a top side by a smooth end region. In other words, the depressions are concave regions in the substrate, the deepest point of which is in each case formed by a smooth end region. Furthermore, the elevations are convex regions in the substrate, the highest point of which is in each case formed by a smooth end region.

The smooth end regions are preferably arranged laterally spaced apart from one another. In an advantageous embodiment of the semiconductor chip, the smooth end regions are arranged in a common plane. The smooth end regions are preferably at the same height. Here, the end regions may be slightly different from one another in height caused by the production process, whereas deviations from the ideal height of up to 10% are possible. Said ideal height may be the average height of the elevations. In particular, the end regions are arranged in a common plane next to one another and do not have a connection arranged in the common plane, wherein directly neighboring end regions touch one another in one point at the most. Preferably, however, the distance between directly neighboring end regions is greater than zero. A smallest distance between directly neighboring end regions is 0.5 μm to 6 μm, for example.

In contrast, a conventional structured sapphire substrate typically has one single continuous smooth region interrupted by depressions or elevations. Thus, the structure described herein particularly constitutes the inversion of a conventional structure. As will be explained in greater detail in the following, crystal quality and thus internal quantum efficiency may be improved by the described separation of smooth regions, said regions preferably serving as growth surfaces. The reason for this lays with the fact that in epitaxial growth, said separate smooth end regions and the accompanying reduced growth area result in a reduction of dislocation density on the one hand and in a reduced formation of stress on the other hand, and in an improvement of crystal quality as a result.

The depressions or elevations at the surface of the substrate may each be delimited by a smooth end region and at least one side surface. In particular, the depressions or elevations are delimited laterally by at least one side surface. In a cross-sectional view, the side surface is preferably arranged at a right angle relative to the end region sectionally at the most. Furthermore, in a cross-sectional view, the side surface runs largely inclined relative to the end region, i.e., not in parallel. The depressions or elevations each comprise an at least inclined and/or curved side surface relative to the end regions. In a cross-sectional view, the side surface may have a kink or curvature. The side surface preferably at least sectionally encloses an angle between 5° and 85°, in particular between 30° and 70°, with the surface normal of the smooth end region.

Advantageously, in the structure provided herein, the ratio of side surfaces running inclined or side surfaces running partially inclined may be increased compared to a conventional structure, thus improving the radiation efficiency.

According to at least one embodiment, the smooth end regions have a two-dimensional shape. This means in particular that an end region extends within one plane only. Here, the size of the end region is determined by a first lateral dimension along a first extension direction and by a second lateral dimension along a second extension direction, with the first and second extension directions particularly running perpendicular to one another, spanning the plane in which the end region extends. The lateral dimensions range particularly between 0.3 μm and 2 μm.

The end regions preferably have a two-dimensional symmetric shape. The two-dimensional shape of an end region may be round or polygonal. Here, “round” is to be understood as a symmetric shape without corners, e.g., an oval or elliptic shape, in particular a circular shape. Preferred polygonal shapes are triangular or hexagonal, for example. Particularly preferably, the polygonal shape resembles an equilateral triangle or a regular hexagon.

Advantageously, in the structure described herein, the ratio of inclined side surfaces may be increased compared to a conventional structure in particular by means of the symmetric shape of the smooth end regions. Because, even with the ratio of inclined side surfaces increased and thus the distance between the end regions reduced, fewer or no asymmetric constrictions arise in the structure described herein. In contrast, an increased number of asymmetric constrictions occurs in a conventional structure, in which a highly decreased or increased nucleation of AlInGaN and thus crystal defects may occur between the depressions or elevations, which in turn decreases crystal quality.

The structure described herein thus allows an improved crystal quality as well as improvement of the internal quantum efficiency as well as radiation efficiency.

According to at least one embodiment, the depressions each have a three-dimensional shape. The three-dimensional shape is preferably symmetric, e.g., radial-symmetric or rotation-symmetric. The three-dimensional shape of the depressions may, for example, resemble an inverted truncated rotational body or a truncated polyhedron, such as an inverted truncated cone or truncated pyramid. Accordingly, the elevations may each have a three-dimensional shape, which is symmetric, for example, rotation-symmetric or radial-symmetric. In particular, the three-dimensional shape resembles a truncated rotational body or a truncated polyhedron, such as a truncated cone or a truncated pyramid. The depressions or elevations have a height between 0.5 μm and 5 μm, for example. The height particularly indicates a vertical dimension which is determined along a third extension direction, preferably perpendicular to the first and second extension direction.

According to at least one embodiment the end regions are arranged regularly. In other words, the regions are not arranged randomly viewed in a top view of the surface of the substrate, but follow a well-discernable regular pattern in the arrangement thereof. Here, deviations from the regular pattern may occur due to production reasons, with the positions of the end regions deviating by 10% max from their ideal position. The end regions may be arranged on lattice points of a hexagonal or cubic lattice, for example. According to at least one configuration of the semiconductor chip, substrate regions arranged between the end regions are designed to be uneven, i.e., not smooth. In other words, the substrate may in particular not comprise further smooth end regions besides the smooth end regions on the surface contacting the semiconductor layer sequence. However, as an alternative, it is possible for further substrate regions to be designed evenly. Said regions are preferably arranged in a manner laterally spaced apart from one another, just like the smooth end regions.

In a preferred embodiment of the semiconductor chip, the surface of the substrate provided with a structure is arranged within the semiconductor chip. In other words, the surface does not form an outer surface of the semiconductor chip here. Preferably, it forms a boundary surface within the semiconductor chip. Outer surfaces of the semiconductor chip may particularly be formed evenly, facilitating the arrangement of contact structures on the outer surfaces and the arrangement of the semiconductor chip on a carrier, respectively.

According to at least one embodiment, at least one layer of the semiconductor layer sequence is formed of AlₙGaₘIn₁₋ₙ₋ₘN, with o≦n≦1, o≦m≦1 and n+m≦1. Preferably, the semiconductor layer sequence comprises an n-conducting region, a p-conducting region and an active zone arranged therebetween. The n-conducting region is preferably arranged between the active zone and the substrate, while the p-conducting region is arranged on a side of the active zone facing away from the substrate. In particular, the active zone is provided for the generating of radiation.

According to at least one embodiment, the substrate is formed of sapphire. Such a substrate is preferably permeable for blue light, which is preferably emitted by an active zone based on AlInGaN. In other words, the substrate may have a transmission coefficient for blue light of at least 80%, preferably at least 90%.

According to at least one embodiment of a method for producing a semiconductor chip, said method comprises the following steps:

Structuring a substrate, wherein depressions are introduced in the substrate or elevations are formed out of the substrate such that the substrate has a structure of depressions at a surface which are each delimited by a smooth end region at the underside, or has a structure of elevations which are each delimited by a smooth end region at the top side, wherein the end regions are arranged laterally spaced from one another,

Growing a semiconductor layer sequence on the surface such that the semiconductor layer sequence is in contact with the surface.

The depressions or elevations in the substrate may be produced by means of etching such as reactive ion etching, RIE for short, for example. Furthermore, the semiconductor layer sequence may be produced particularly by means of metalorganic vapor phase epitaxy, MOVPE for short.

In a preferred embodiment of the method, seeding the surface by semiconductor material of the semiconductor layer sequence takes place on the smooth end regions. Thus, the smooth end regions preferably serve as a growth surface. As a result of the lateral spacing or separation of the smooth end regions and the accompanying smaller growth area, dislocation density may be reduced compared to conventional structures. Fewer dislocations occur on the growth surface. Furthermore, the dislocation density may be controlled further by selecting suitable process conditions. Here, in particular the ratio of the starting materials such as trimethylgallium and ammonia used for the semiconductor layer sequence, the change of temperature, the processing pressure and the growth rate play a decisive role.

When producing the semiconductor layer sequence, the depressions are filled with semiconductor material of the semiconductor layer sequence, preferably starting from the smooth end regions. Thus, the depressions are filled with semiconductor material of the semiconductor layer sequence and surrounded by substrate material in the finished semiconductor chip. If growth takes place on the smooth end regions of the elevations, recessed substrate regions arranged between the smooth end regions are preferably as well filled with semiconductor material of the semiconductor layer sequence after finishing the semiconductor layer sequence. Thus, in the finished semiconductor chip, elevations formed of the material of the substrate are as well surrounded by the semiconductor material sequence of the semiconductor layer.

In an alternative embodiment of the method, seeding of the surface by means of semiconductor material of the semiconductor layer sequence takes place on the side surfaces. Here, side surfaces are preferably arranged to have a greater angle relative to the surface normal of the end region than is the case in seeding the smooth end regions.

### BRIEF DESCRIPTION OF THE DRAWINGS

Further advantages and advantageous embodiments and developments result from the embodiments described in the following in conjunction with FIGS. 1 to 9.

The figures show in:

FIG. 1 a schematic cross-sectional view of a semiconductor chip according to an exemplary embodiment,

FIGS. 2A to 2D schematic cross-sectional views of various exemplary embodiments of structures with which the surface of a structured substrate described herein may be provided,

FIGS. 3A to 3D and 4A to 4C schematic top views of the surface of a structured substrate described herein according to various exemplary embodiments,

FIGS. 5A to 5C different production steps of a method for producing a semiconductor chip according to a first exemplary embodiment,

FIGS. 6A to 6C different production steps of a method for producing a semiconductor chip according to a second exemplary embodiment,

FIGS. 7A to 7C and FIGS. 8A to 8B different views of a structure of a conventional substrate,

FIG. 9 a graph illustrating the ratio of inclined side surfaces in different surface structures of a structured substrate.

### DETAILED DESCRIPTION OF ILLUSTRATIVE EMBODIMENTS

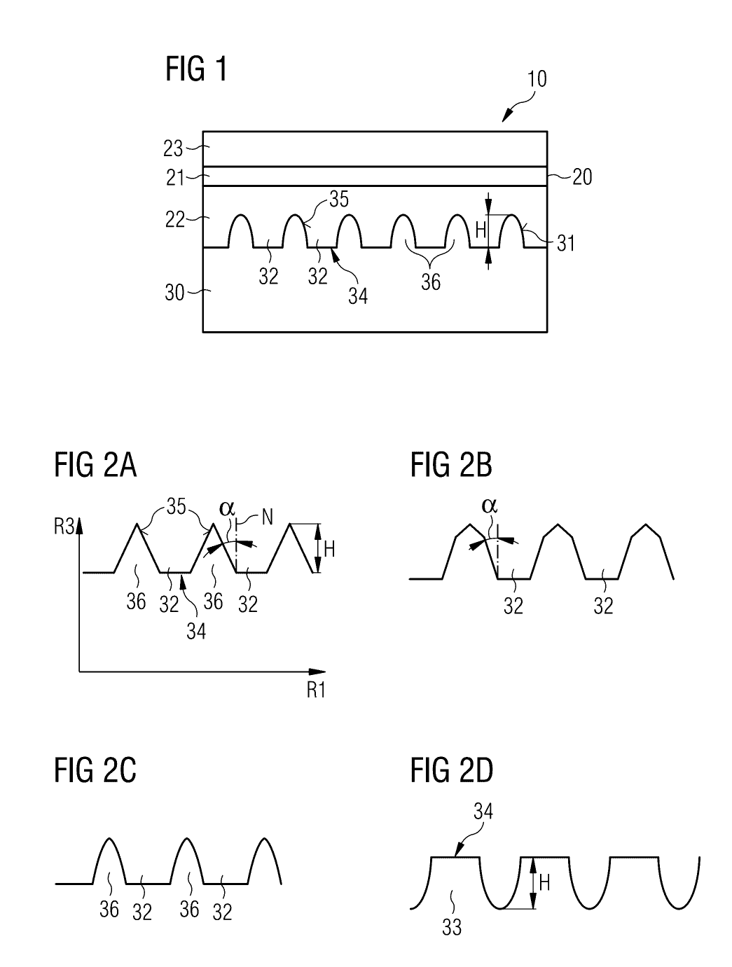

FIG. 1 shows an exemplary embodiment of a semiconductor chip 10 as described herein. Semiconductor chip 10 comprises a semiconductor layer sequence 20. Here, at least one layer of the semiconductor layer sequence 20 is formed of AlₙGaₘIn₁₋ₙ₋ₘN, with o≦n≦1, o≦m≦1 and n+m≦1. The semiconductor layer sequence 20 further comprises an active zone 21 which is particularly provided for the generation of radiation, as well as an n-conducting region 22 and a p-conducting region 23. The active zone 21 is arranged between the n-conducting region 22 and the p-conducting region 23.

The semiconductor chip 10 further comprises a structured substrate 30 on which the semiconductor layer sequence 20 is arranged. The substrate 30 is preferably formed of sapphire and thus particularly suitable for decoupling blue light which is preferably emitted by the active zone 21 when using AlInGaN for said active zone 21. The substrate 30 is in contact with the semiconductor layer sequence 20 at a surface 31. In this exemplary embodiment, the n-conducting region 22 of the semiconductor layer sequence 20 is adjacent to the surface 31. Said surface 31 is arranged within the semiconductor chip 10, for example, and provided for increasing the radiation efficiency.

The substrate 30 comprises a structure of depressions 32 at the surface 31. The depressions 32 are each delimited by a smooth end region 34 at the underside. Said smooth end regions 34 are arranged in a common plane. Preferably, the smooth end regions 34 are all located at the same height. Furthermore, the depressions 32 are each laterally delimited by a side surface 35. In the exemplary embodiment illustrated in FIG. 1, the side surfaces 35 are provided with a curvature when viewed in a cross-section. The depressions 32 are formed to be rotation-symmetric here and, in particular, have the shape of a truncated hyperboloid.

The depressions 32 introduced into the substrate 30 are surrounded by substrate regions 36 which are designed to be uneven, i.e., not smooth. In a cross-sectional view, the substrate regions 36 have the shape of an inverted parabola.

FIGS. 2A to 2D show further possible structures with which the surface of the substrate may be provided. The three-dimensional shape of the depressions 32 may resemble an inverted truncated cone or a truncated pyramid, for example, (see FIG. 2A). Here, the depressions 32 may be surrounded by substrate regions 36 which have a triangular shape when viewed in a cross-section. The side surfaces 35 of the depressions 32 enclose an angle a with the surface normals of the end regions 34, said angle preferably ranging between 5° and 85°, in particular between 30° and 70°. Furthermore, the side surfaces 35 of the depressions 32 may have a kink when viewed in a cross-section (see FIG. 2B). Here, in particular a part of the side surfaces 35 adjacent to the respective end region 34 runs at an angle a between 5° and 85°, in particular between 30° and 70°, relative to the end region 34. The structure illustrated in FIG. 2C comprises depressions 32 with curved side surfaces 35 just like the structure illustrated in FIG. 1. However, in contrast to the structure illustrated in FIG. 1, the surrounding substrate regions 36 do not have a rounded but a pointed end region.

While FIGS. 1 and 2A to 2C show structures of depressions 32, FIG. 2D illustrates a structure of elevations 33, which are each delimited by a smooth end region 34 at the top side. Said elevations 33 each have a three-dimensional shape, said shape being symmetric. The three-dimensional shape resembles a truncated hyperboloid. The structure illustrated in FIG. 2D presents an inversion of the structure illustrated in FIG. 1.

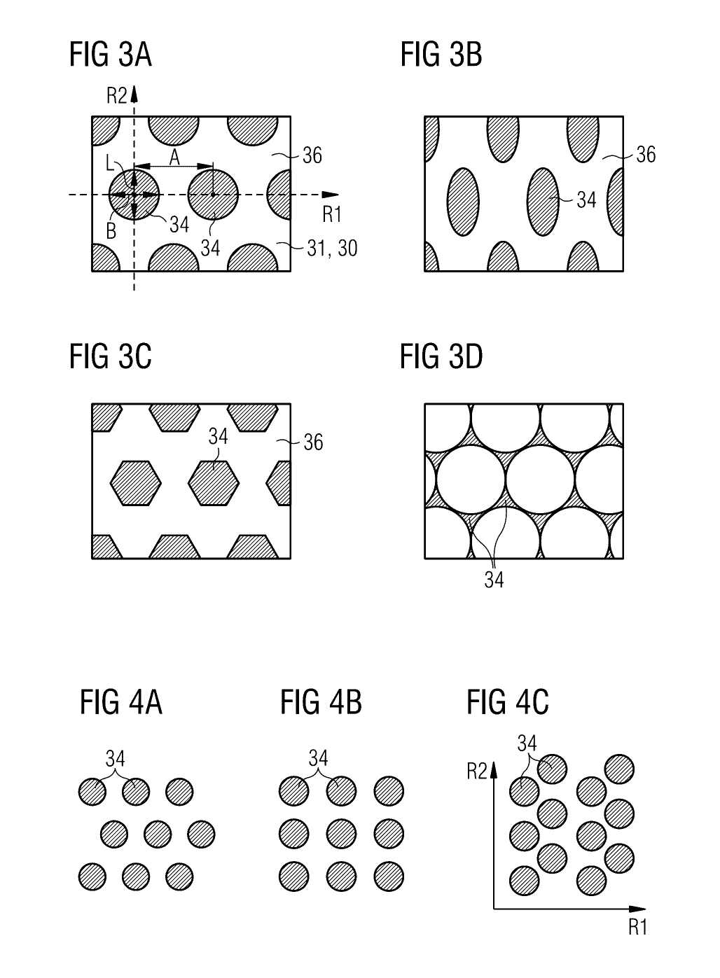

The size of the end regions 34 is determined by a first lateral dimension B along a first extension direction R1 and by a second lateral dimension L along a second extension direction R2, wherein the first and second extension directions R1, R2 span the plane in which the end region 34 extends (see FIG. 3A). The lateral dimensions B, L range particularly between 0.3 μm and 2 μm. The height H of the depressions 32 or elevations 33 is determined along a third extension direction R3, which preferably runs parallel to the surface normal N of the end region 34 and perpendicular to the first and second extension directions R1, R2. The depressions 32 or elevations 33 have a height H between 0.5 μm and 5 μm, for example, (see FIGS. 2A and 2D).

FIG. 3A shows a schematic top view of surface 31 of the substrate 30 illustrated in FIG. 1, FIG. 1 showing a cross-section of substrate 30 along a dashed line R1. As can be seen from FIG. 3A, the smooth end regions 34 have a circular, two-dimensional shape.

Furthermore, the smooth end regions 34 are arranged laterally spaced from one another. This means that the smooth end regions 34 are separated regions that do not have a connection to one another in a plan view of the surface 31, in particular any connection arranged in the same plane as the end regions 34. The smallest distance A between directly neighboring end regions 34 is 0.5 μm to 15 μm, for example.

FIGS. 3B and 3C show further possible shapes of the two-dimensional shape of the smooth end regions 34. The shape may be oval or ellipsoid, for example, (see FIG. 3B). Furthermore, the shape may resemble a regular polygon, in particular a regular hexagon, (see FIG. 3C).

FIG. 3D shows a limit case of a structure in which directly neighboring end regions 34 touch in one point only. Here, the form of the two-dimensional shape of the smooth end regions 34 resembles a triangle, with the sides of the triangle running in a curved manner.

The end regions 34 of the structures illustrated in FIGS. 3A to 3D are arranged regularly and follow an obvious, regular pattern in the arrangements thereof. For example, the end regions 34 may be arranged at lattice points of a hexagonal lattice (see FIG. 4A) or cubic lattice (see FIG. 4B) or follow any other regular pattern, wherein in particular the end regions 34 which are arranged along one of the two lateral extension directions R1, R2 can be transformed into one another by a single translation along the plane spanned by the two lateral extension directions R1, R2 (see FIG. 4C).

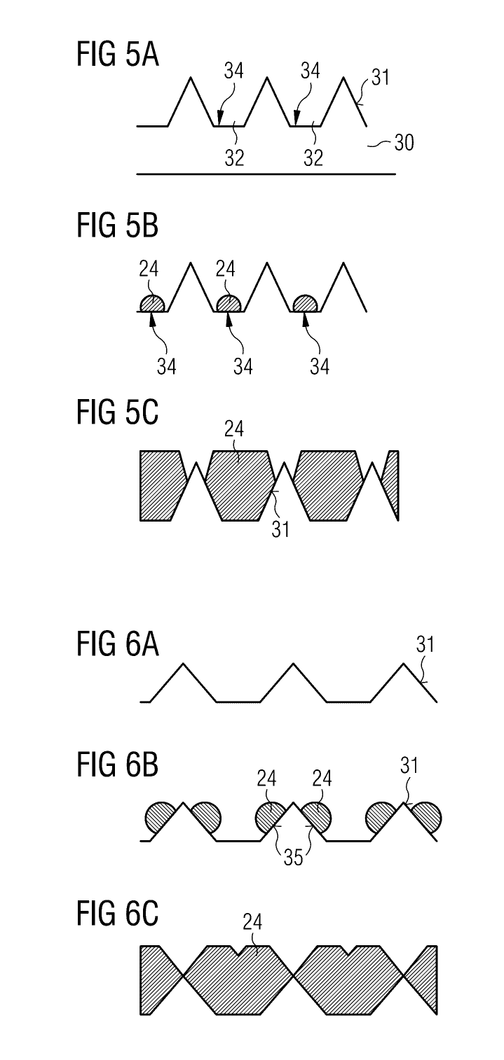

A first exemplary embodiment of a method for producing a semiconductor chip is described in conjunction with FIGS. 5A to 5C. Here, a substrate 30 is structured, wherein depressions 32 are formed in the substrate 30 in such a way that the substrate 30 at a surface 31 has a structure of depressions 32 each delimited at the underside by a smooth end region 34, with the end regions 34 being arranged laterally spaced from one another (see FIG. 5A). In a next step, surface 31 is seeded by semiconductor material 24 of the semiconductor layer sequence, with the seeding taking place on the smooth end regions 34. The smooth end regions 34 thus serve as a growth surface (see FIG. 5B). When continuing the growth, the depressions 32, starting from the smooth end regions 34 are filled with semiconductor material 24 of the semiconductor layer sequence (see FIG. 5C). When growing further, gaps within the semiconductor layer sequence are closed so that the sequence is in contact with the entire surface 31 (not illustrated) after finishing the growth process.

In an alternative embodiment of the method, seeding of surface 31 by means of semiconductor material of the semiconductor layer sequence takes place on the side surfaces 35 (see FIGS. 6a to 6C). In this case, the side surfaces 35 are preferably arranged at a greater angle relative to the surface normal of the end region 34 than is the case in seeding the smooth end regions.

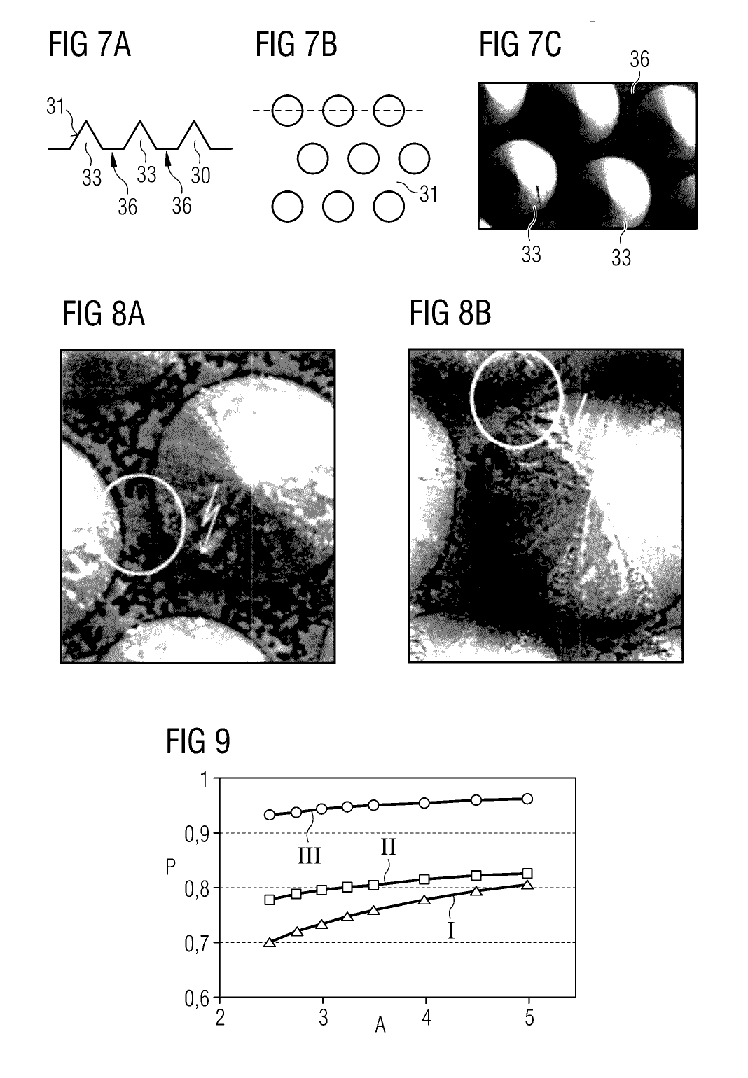

FIGS. 7A to 7C show a structure of a conventional substrate 30. As can be taken from FIGS. 7A and 7C, the structure has conical elevations 33. FIG. 7A shows a cross-section along the dashed line illustrated in FIG. 7B. FIG. 7B shows a top view of the surface 31 of substrate 30. FIG. 7C shows an image taken by means of a scanning electron microscope (SEM) of such a structure. The conical elevations 33 are surrounded by smooth substrate regions 36 formed in a continuous fashion (see FIG. 7C). The structure described herein, for example, in conjunction with FIGS. 1, 2A to 2D and 3A to 3D thus particularly presents the inversion of the conventional structure, since the smooth end regions are interrupted and do not have any connection to one another when viewed in a surface top view in the structure described herein.

Conventionally, growth of the semiconductor layer sequence takes place on the smooth, continuously-formed substrate regions 36. However, substrate regions 36 have asymmetric constrictions between directly neighboring elevations 33, in which a highly decreased or increased nucleation of AlInGaN and thus crystal defects may occur, particularly if the constrictions are designed to be relatively narrow as a result of inclined side surfaces. This problem is illustrated in FIGS. 8A and 8B. The encircled region in FIG. 8A has a region of decreased nucleation of AlInGaN, while the encircled region of FIG. 8B has a region of increased nucleation of AlInGaN at the constriction, with the black regions presenting regions of increased nucleation of AlInGaN and the grey regions presenting regions of decreased nucleation of AlInGaN. Advantageously, such irregular seeding may largely be prevented by means of the structure described above. This may particularly be achieved by the symmetric shape of the smooth end regions and the lateral spacing thereof.

Furthermore, separation of the smooth end regions or the symmetric shape thereof, allows an increase of the ratio of inclined side surfaces without having to fear constrictions of highly-decreased or highly-increased nucleation of AlInGaN.

FIG. 9 shows a graph with the horizontal axis indicating the distance A between directly neighboring smooth end regions in μm, and the vertical axis P indicating the ratio of inclined side surfaces. Curve I illustrates the situation in a conventional structure with conical elevations in hexagonal arrangement. Curve II illustrates the situation in a structure described herein in a cubic arrangement, and curve III illustrates the situation in a structure described herein in a hexagonal arrangement. As can be taken from the graph, in the structures described herein, advantageously the ratio of inclined side surfaces can be increased compared to a conventional structure. The calculations of the inventors were based upon the assumptions that the smallest lateral dimensions of the end regions are approximately 0.3 μm and that approximately the same height of deposited thickness as the lateral dimensions is required when growing over depressions and elevations, respectively. Depending on the selection of the assumption, the parameters vary slightly, but the results described above are maintained.

The present application claims priority of German patent application DE 10 2014 108 301.6, the disclosure of which is incorporated herein by reference.

The invention is not limited by the description by means of the exemplary embodiments. The invention rather comprises any new feature as well as any combination of features, particularly including any combination of features in the claims, even if said feature or said combination per se is not explicitly indicated in the patent claims or exemplary embodiments.

1-15. (canceled)

16. A semiconductor chip comprising:
a semiconductor layer sequence; and
a structured substrate comprising a surface, wherein the structured substrate is in contact with the semiconductor layer sequence at said surface, wherein the structured substrate has at the surface a structure of depressions, each depression is delimited at an underside by a smooth end region, or wherein the surface has a structure of elevations, each elevation is delimited at a top side by a smooth end region, and wherein the end regions are laterally spaced apart with respect to one another.

17. The semiconductor chip according to claim 16, wherein the end regions are arranged in a common plane.

18. The semiconductor chip according to claim 17, wherein the end regions are arranged next to one another in the common plane and do not have a connection arranged in the common plane, and wherein directly neighboring end regions touch one another in one point at the most.

19. The semiconductor chip according to claim 16, wherein the end regions have a two-dimensional shape, which is round or polygonal.

20. The semiconductor chip according to claim 16, wherein the end regions have a two-dimensional shape, which is symmetric.

21. The semiconductor chip according to claim 16, wherein the end regions are arranged regularly.

22. The semiconductor chip according to claim 16, wherein the end regions are arranged at lattice points of a hexagonal or cubic lattice.

23. The semiconductor chip according to claim 16, wherein each depression or elevation is delimited by the end region and at least one side surface, and wherein the at least one side surface, in a cross-sectional view, is arranged at a right angle relative to the end region sectionally at the most.

24. The semiconductor chip according to claim 23, wherein the at least one side surface has a kink or a curvature in a cross-sectional view.

25. The semiconductor chip according to claim 16, wherein each depression has a three-dimensional shape that resembles an inverted truncated rotational body or a truncated polyhedron.

26. The semiconductor chip according to claim 16, wherein each elevation has a three-dimensional shape that resembles an inverted truncated rotational body or a truncated polyhedron.

27. The semiconductor chip according to claim 16, wherein the semiconductor layer sequence comprises AlₙGaₘIn₁₋ₙ₋ₘN, with o≦n≦1, o≦m≦1 and n+m≦1, and wherein the substrate comprises sapphire.

28. A method for producing a semiconductor chip, the method comprising:
structuring a substrate, wherein depressions are introduced into the substrate or elevations are formed out of the substrate so that the substrate at a surface has a structure of depressions which are each delimited at an underside by a smooth end region, or has a structure of elevations which are each delimited at a top side by a smooth end region, and wherein the end regions are laterally spaced from one another; and
growing a semiconductor layer sequence on the surface such that the semiconductor layer sequence is in contact with the surface.

29. The method according to the claim 28, further comprising seeding a semiconductor material of the semiconductor layer sequence on the smooth end regions.

30. The method according to claim 28, wherein each depression or elevation is delimited by the end region and at least one side surface, and further comprising seeding a semiconductor material of the semiconductor layer sequence on the side surfaces.

31. The method according to claim 13, wherein the depressions or elevations have the shape of a truncated hyperboloid.

32. A semiconductor chip, comprising:
a semiconductor layer sequence,
a structured substrate, which at a surface is in contact with the semiconductor layer sequence and has at said surface a structure of depressions which have the shape of a truncated hyperboloid and are each delimited at the underside by a smooth end region, or has a structure of elevations which have the shape of a truncated hyperboloid and are each delimited at the top side by a smooth end region, wherein the end regions are arranged in a manner spaced apart laterally with respect to one another.
